(19) United States
(12) Patent Application Publication
(10) Pub. No.: US 2025/0160121 A1
(43) Pub. Date: May 15, 2025

(54) DISPLAY DEVICE MANUFACTURING METHOD

(71) Applicant: Japan Display Inc., Tokyo (JP)

(72) Inventor: Hiroshi OGAWA, Tokyo (JP)

(73) Assignee: Japan Display Inc., Tokyo (JP)

(21) Appl. No.: 18/940,883

(22) Filed: Nov. 8, 2024

(30) Foreign Application Priority Data
Nov. 13, 2023 (JP) 2023-193014

(51) Int. Cl. H10K 59/12

(52) U.S. Cl. CPC H10K 59/1201

(57) ABSTRACT

According to one embodiment, a display device manufacturing method includes forming a lower electrode, forming an insulating layer on the lower electrode, forming a partition including a lower portion provided above the insulating layer and an upper portion having an end portion protruding relative to a side surface of the lower portion, providing a resist covering the partition on the insulating layer, forming a rib and a pixel aperture surrounded by the rib by removing a portion exposed from the resist of the insulating layer by etching, and forming an organic layer covering the lower electrode through the pixel aperture and emitting light in response to application of a voltage. The end portion of the upper portion is exposed from the resist in the etching.

### CROSS-REFERENCE TO RELATED APPLICATION

This application is based upon and claims the benefit of priority from Japanese Patent Application No. 2023-193014, filed Nov. 13, 2023, the entire contents of which are incorporated herein by reference.

### FIELD

Embodiments described herein relate generally to a display device manufacturing method.

### BACKGROUND

Recently, display devices with organic light-emitting diodes (OLED) applied thereto as display elements have been put into practical use. In this type of display devices, a technique which can improve yields and reliability is required.

### BRIEF DESCRIPTION OF THE DRAWINGS

FIG. 1 is a view showing a configuration example of a display device according to an embodiment.

FIG. 2 is a schematic plan view showing an example of the layout of subpixels.

FIG. 3 is a schematic cross-sectional view of the display device along the III-III line of FIG. 2.

FIG. 4 is a view showing an example of a layer structure applicable to organic layers.

FIG. 5 is a schematic cross-sectional view showing an example of a structure applicable to a partition.

FIG. 6 is a schematic cross-sectional view showing a manufacturing process of the display device of the present embodiment.

FIG. 7 is a schematic cross-sectional view showing a process following FIG. 6.

FIG. 8A is a schematic cross-sectional view showing a process following FIG. 7.

FIG. 8B is a schematic cross-sectional view showing a process following FIG. 8A.

FIG. 8C is a schematic cross-sectional view showing a process following FIG. 8B.

FIG. 8D is a schematic cross-sectional view showing a process following FIG. 8C.

FIG. 9 is a schematic cross-sectional view showing a process following FIG. 8D.

FIG. 10 is a schematic cross-sectional view showing a process following FIG. 9.

FIG. 11 is a schematic cross-sectional view showing a process following FIG. 10.

FIG. 12 is a schematic cross-sectional view showing a process following FIG. 11.

FIG. 13 is a schematic cross-sectional view showing a process following FIG. 12.

FIG. 14 is a schematic cross-sectional view showing a process following FIG. 13.

FIG. 15 is a schematic cross-sectional view showing a process following FIG. 14.

### DETAILED DESCRIPTION

In general, according to one embodiment, a display device manufacturing method includes: forming a lower electrode; forming an insulating layer on the lower electrode; forming a partition including a lower portion provided above the insulating layer and an upper portion having an end portion protruding relative to a side surface of the lower portion; providing a resist covering the partition on the insulating layer; forming a rib and a pixel aperture surrounded by the rib by removing a portion exposed from the resist of the insulating layer by etching; forming an organic layer covering the lower electrode through the pixel aperture and emitting light in response to application of a voltage; and forming an upper electrode covering the organic layer, wherein the end portion of the upper portion is exposed from the resist in the etching.

The present embodiment can provide a manufacturing method of a display device capable of improving yields.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction along the X-axis is referred to as a first direction X, a direction along the Y-axis is referred to as a second direction Y, and a direction along the Z-axis is referred to as a third direction Z. The third direction Z is a normal direction relative to a plane including the first direction X and the second direction Y. A plan view is defined as appearance when various types of elements are viewed parallel to the third direction Z.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

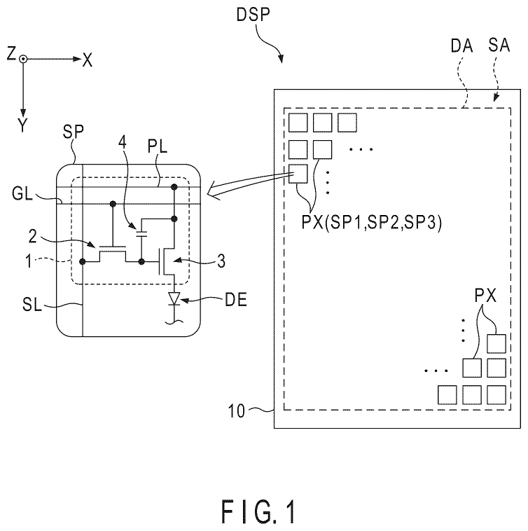

FIG. 1 is a view showing a configuration example of a display device DSP according to an embodiment. The display device DSP comprises an insulating substrate 10. The substrate 10 has a display area DA which displays an image and a surrounding area SA around the display area DA. The substrate 10 may be glass or a resinous film having flexibility.

In the present embodiment, the substrate 10 is rectangular as seen in plan view. The shape of the substrate 10 in plan view is not limited to a rectangle and may be another shape such as a square, a circle or an oval.

The display area DA includes a plurality of pixels PX arrayed in a matrix in the first direction X and the second direction Y. Each pixel PX includes a plurality of subpixels SP which display different colors. This embodiment assumes a case where each pixel PX includes a blue subpixel SP1, a green subpixel SP2, and a red subpixel SP3. However, each pixel PX may include a subpixel SP which exhibits another color such as white in addition to the subpixels SP1, SP2, and SP3 or instead of one of the subpixels SP1, SP2, and SP3.

The sub-pixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A plurality of scanning lines GL supplying a scanning signal to the pixel circuit 1 of each subpixel SP, a plurality of signal lines SL supplying a video signal to the pixel circuit 1 of each subpixel SP, and a plurality of power lines PL are provided in the display area DA. In the example of FIG. 1, the scanning lines GL and the power lines PL extend in the first direction X, and the signal lines SL extend in the second direction Y.

A gate electrode of the pixel switch 2 is connected to the scanning line GL. A source electrode of the pixel switch 2 is connected to the signal line SL. A drain electrode of the pixel switch 2 is connected to a gate electrode of the drive transistor 3 and the capacitor 4. A source electrode of the drive transistor 3 is connected to the power line PL and the capacitor 4. The drain electrode of the drive transistor 3 is connected to the display element DE.

The configuration of the pixel circuit 1 is not limited to the example of the figure. For example, the pixel circuit 1 may comprise more thin-film transistors and capacitors.

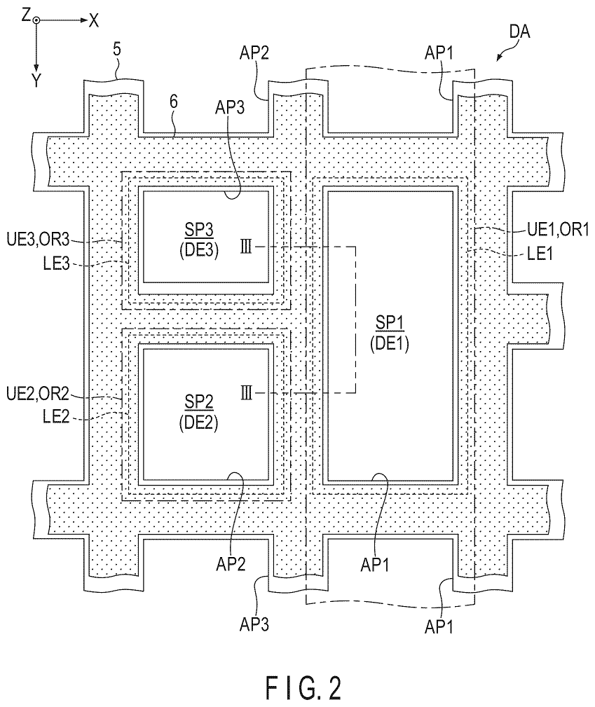

FIG. 2 is a schematic plan view showing an example of the layout of the subpixels SP1, SP2, and SP3. In the example of FIG. 2, each of the subpixels SP2 and SP3 is adjacent to the subpixel SP1 in the first direction X. Further, the subpixels SP2 and SP3 are arranged in the second direction Y.

When the subpixels SP1, SP2, and SP3 are arranged in this layout, a row in which the subpixels SP2 and SP3 are alternately arranged in the second direction Y and a row in which the plurality of subpixels SP1 are repeatedly arranged in the second direction Y are formed in the display area DA. These rows are alternately arranged in the first direction X. The layout of the subpixels SP1, SP2, and SP3 is not limited to the example of FIG. 2.

A rib 5 is arranged in the display area DA. The rib 5 includes pixel apertures AP1, AP2, and AP3 in the subpixels SP1, SP2, and SP3, respectively. In the example of FIG. 2, the pixel aperture AP1 is larger than the pixel aperture AP2, and the pixel aperture AP2 is larger than the pixel aperture AP3. Thus, among the subpixels SP1, SP2, and SP3, the aperture ratio of the subpixel SP1 is the greatest, and the aperture ratio of the subpixel SP3 is the least. The size of each of the pixel apertures AP1, AP2, and AP3 is not limited to the example of the figure. For example, the pixel apertures AP2 and AP3 may have the same size.

The subpixel SP1 comprises a lower electrode LE1, an upper electrode UE1, and an organic layer OR1, which overlap with the pixel aperture AP1. The subpixel SP2 comprises a lower electrode LE2, an upper electrode UE2, and an organic layer OR2, which overlap with the pixel aperture AP2. The subpixel SP3 comprises a lower electrode LE3, an upper electrode UE3, and an organic layer OR3, which overlap with the pixel aperture AP3.

Portions which overlap with the pixel aperture AP1 of the lower electrode LE1, the upper electrode UE1, and the organic layer OR1 constitute a display element DE1 of the subpixel SP1. Portions which overlap with the pixel aperture AP2 of the lower electrode LE2, the upper electrode UE2, and the organic layer OR2 constitute a display element DE2 of the subpixel SP2. Portions which overlap with the pixel aperture AP3 of the lower electrode LE3, the upper electrode UE3, and the organic layer OR3 constitute a display element DE3 of the subpixel SP3. Each of the display elements DE1, DE2, and DE3 may further include a cap layer to be described later. The rib 5 surrounds each of the display elements DE1, DE2, and DE3.

A partition 6 is provided in the display area DA. The partition 6 is located in the upper side of the rib 5 to entirely overlap with the rib 5. In the example of FIG. 2, the partition 6 has a planar shape similar to that of the rib 5. In other words, the partition 6 includes an aperture in each of the subpixels SP1, SP2, and SP3. From another viewpoint, each of the rib 5 and the partition 6 has a grating shape as seen in plan view and surrounds each of the display elements DE1, DE2, and DE3. The partition 6 functions as lines which apply common voltage to the upper electrodes UE1, UE2, and UE3.

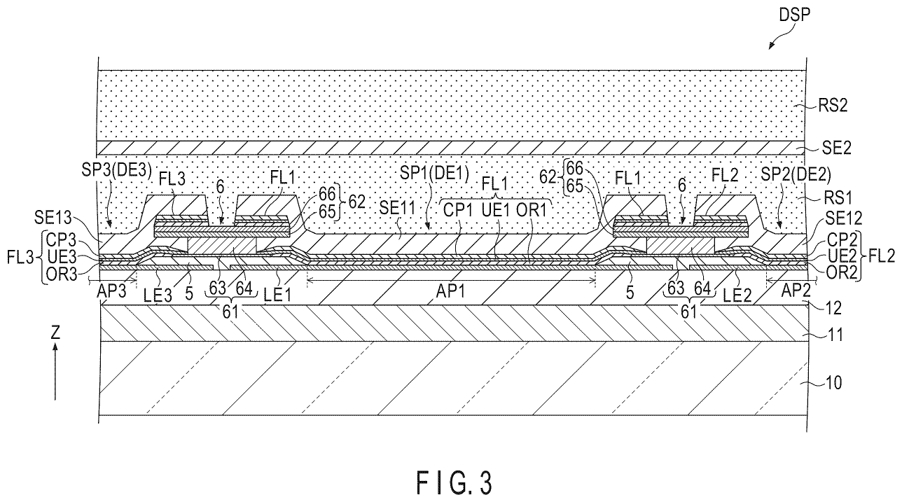

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, the scanning lines GL, the signal lines SL, and the power lines PL shown in FIG. 1. The circuit layer 11 is covered with an organic insulating layer 12. The organic insulating layer 12 functions as a planarization film which planarizes irregularities formed by the circuit layer 11.

The lower electrodes LE1, LE2, and LE3 are provided on the organic insulating layer 12. The rib 5 is provided on the organic insulating layer 12 and the lower electrodes LE1, LE2, and LE3. End portions of the lower electrodes LE1, LE2, and LE3 are covered with the rib 5. Although not shown in the section in FIG. 3, the lower electrodes LE1, LE2, and LE3 are connected to the respective pixel circuits 1 (drain electrode of the drive transistor 3 shown in FIG. 1) of the circuit layer 11 through respective contact holes provided in the organic insulating layer 12.

The partition 6 includes a conductive lower portion 61 provided on the rib 5 and an upper portion 62 provided on the lower portion 61. The upper portion 62 has a width greater than that of the lower portion 61. This configuration allows the both end portions of the upper portion 62 to protrude relative to the side surfaces of the lower portion 61. This shape of the partition 6 is called an overhang shape.

In the example of FIG. 3, the lower portion 61 includes a bottom layer 63 and a stem layer 64. The bottom layer 63 is located between the stem layer 64 and the rib 5 and is formed to be thinner than the stem layer 64. In the example of FIG. 3, the both end portions of the bottom layer 63 protrude relative to the side surfaces of the stem layer 64. Further, the both end portions of the bottom layer 63 are located between the end portion of the upper portion 62 and the side surface of the stem layer 64 in plan view.

In the example of FIG. 3, the upper portion 62 includes a first top layer 65 and a second top layer 66. The first top layer 65 is provided on the stem layer 64 of the lower portion 61. The second top layer 66 is provided on the first layer 65.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the side surface of the lower portion 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers which improve the extraction efficiency of the light emitted from the organic layers OR1, OR2, and OR3, respectively.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

A part of the stacked film FL1 is located on the upper portion 62. This part is spaced apart from a part which is located around the partition 6 of the stacked film FL1 (in other words, from the part which constitutes the display element DE1). Similarly, a part of the stacked film FL2 is located on the upper portion 62. This part is spaced apart from a part which is located around the partition 6 of the stacked film FL2 (in other words, from the part which constitutes the display element DE2). Similarly, a part of the stacked film FL3 is located on the upper portion 62. This part is spaced apart from a part which is located around the partition 6 of the stacked film FL3 (in other words, from the part which constitutes the display element DE3).

Sealing layers SE11, SE12, and SE13, which respectively cover the stacked films FL1, FL2, and FL3 are respectively provided in the subpixels SP1, SP2, and SP3. More specifically, the sealing layer SE11 continuously covers the cap layer CP1 and the partition 6 around the subpixel SP1. The sealing layer SE12 continuously covers the cap layer CP2 and the partition 6 around the subpixel SP2. The sealing layer SE13 continuously covers the cap layer CP3 and the partition 6 around the subpixel SP3.

In the example of FIG. 3, the stacked film FL1 and the sealing layer SE11 located on the partition 6 between the subpixels SP1 and SP2 are spaced apart from the stacked film FL2 and the sealing layer SE12 located on this partition 6. The stacked film FL1 and the sealing layer SE11 located on the partition 6 between the subpixels SP1 and SP3 are spaced apart from the stacked film FL3 and the sealing layer SE13 located on this partition 6.

The sealing layers SE11, SE12, and SE13 are covered with a resin layer RS1. The resin layer RS1 is covered with the sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a protective film, and a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as polyimide. Each of the rib 5 and the sealing layers SE11, SE12, SE13, and SE2 is formed of an inorganic insulating material such as silicon nitride (SiNx), silicon oxide (Siox), or silicon oxynitride (SiON). For example, the rib 5 is formed of silicon oxynitride, and each of the sealing layers SE11, SE12, SE13, and SE2 is formed of silicon nitride. Each of the resin layers RS1 and RS2 is formed of, for example, a resinous material (organic insulating material) such as epoxy resin or acrylic resin.

Each of the lower electrodes LE1, LE2, and LE3 has a reflective layer and a pair of conductive oxide layers covering the upper and lower surfaces of the reflective layer. The reflective layer is formed of, for example, a metallic material having excellent light-reflecting properties, such as silver. Each of the conductive oxide layers can be formed of, for example, a transparent conductive oxide such as indium tin oxide (ITO), indium zinc oxide (IZO), or indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

For example, each of the bottom layer 63 and the stem layer 64 of the partition 6 is formed of a metal material. For the metal material of the bottom layer 63, for example, molybdenum (Mo), titanium (Ti), titanium nitride (TiN), a molybdenum-tungsten alloy (MoW) or a molybdenum-niobium alloy (MoNb) can be used. For the metal material of the stem layer 64, for example, aluminum (Al), an aluminum-neodymium alloy (AlNd), an aluminum-yttrium alloy (AlY) or an aluminum-silicon alloy (AlSi) can be used. For example, at least one of the bottom layer 63 and the stem layer 64 may comprise a stacked layer structure in which a plurality of layers are stacked. The stem layer 64 may include a layer formed of an insulating material.

For example, the first top layer 65 is formed of a metal material and the second top layer 66 is formed of a transparent conductive oxide. For the metal material forming the first top layer 65, for example, titanium, titanium nitride, molybdenum, tungsten, a molybdenum-tungsten alloy, or a molybdenum-niobium alloy may be used. For the conductive oxide forming the second top layer 66, for example, ITO, IZO, or IGZO may be used. The upper portion 62 may comprise a single-layer structure of a metal material. The upper portion 62 may further include a layer formed of an insulating material.

Common voltage is applied to the partition 6. This common voltage is applied to each of the upper electrodes UE1, UE2, and UE3 in contact with the side surfaces of the lower portions 61. Pixel voltages according to the video signals of the signal lines SL are applied to the lower electrodes LE1, LE2, and LE3 through the respective pixel circuits 1 provided in the subpixels SP1, SP2, and SP3.

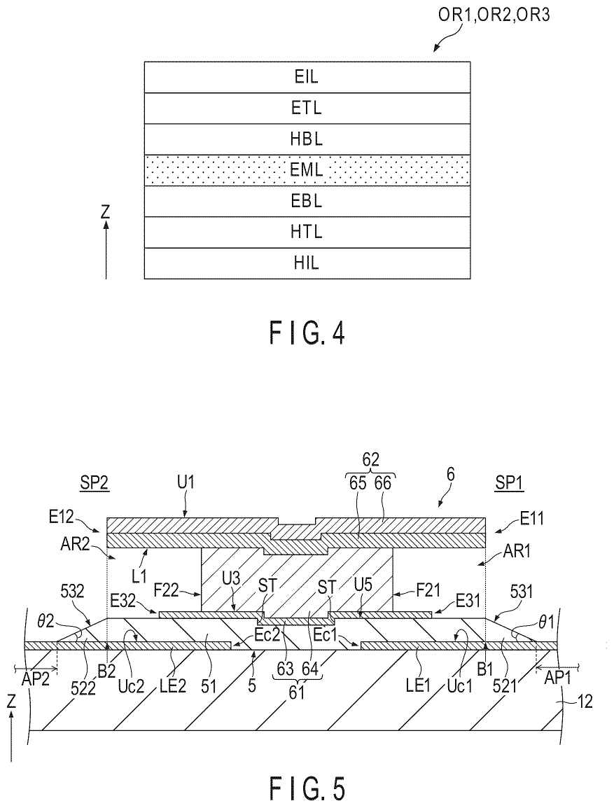

FIG. 4 is a view showing an example of a layer structure applicable to the organic layers OR1, OR2, and OR3. Each of the organic layers OR1, OR2, and OR3 is formed of a plurality of thin films including a light emitting layer EML. The present embodiment assumes a case where each of the organic layers OR1, OR2, and OR3 comprises a structure in which a hole injection layer HIL, a hole transport layer HTL, an electron blocking layer EBL, a light emitting layer EML, a hole blocking layer HBL, an electron transport layer ETL, and an electron injection layer EIL are stacked in this order in the third direction Z. Each of the organic layers OR1, OR2, and OR3 may comprise another structure such as a tandem structure including a plurality of light emitting layers EML.

Each of the cap layers CP1, CP2, and CP3 comprises, for example, a multilayer structure in which a plurality of transparent layers are stacked. These transparent layers may include a layer formed of an inorganic material and a layer formed of an organic material. The transparent layers have refractive indices different from each other. For example, the refractive indices of these transparent layers are different from the refractive indices of the upper electrodes UE1, UE2, and UE3 and the refractive indices of the sealing layers SE11, SE12, and SE13. At least one of the cap layers CP1, CP2, and CP3 may be omitted.

The organic layers OR1, OR2, and OR3 emit light in response to the application of a voltage. More specifically, when a potential difference is formed between the lower electrode LE1 and the upper electrode UE1, the light emitting layer EML of the organic layer OR1 emits light in a blue wavelength range. When a potential difference is formed between the lower electrode LE2 and the upper electrode UE2, the light emitting layer EML of the organic layer OR2 emits light in a green wavelength range. When a potential difference is formed between the lower electrode LE3 and the upper electrode UE3, the light emitting layer EML of the organic layer OR3 emits light in a red wavelength range.

As another example, the light emitting layers EML of the organic layers OR1, OR2, and OR3 may emit light exhibiting the same color (for example, white). In this case, the display device DSP may comprise a color filter that converts the light emitted from the light emitting layers EML into light of the color corresponding to the subpixels SP1, SP2, and SP3. In addition, the display device DSP may comprise a layer including quantum dots that are excited by the light emitted from the light emitting layers EML to generate the light of the colors corresponding to the subpixels SP1, SP2, and SP3.

FIG. 5 is a schematic cross-sectional view showing an example of a structure applicable to the partition 6. FIG. 5 shows a portion which is located between the subpixels SP1 and SP2 of the partition 6 as an example. A structure similar to that of FIG. 5 may be also applied to the portion which is located between the subpixels SP1 and SP3 and the portion which is located between the subpixels SP2 and SP3 of the partition 6.

The upper portion 62 includes an end portion E11 of the subpixel SP1 side and an end portion E12 of the subpixel SP2 side. The first top layer 65 has a lower surface L1. The second top layer 66 has an upper surface U1. The stem layer 64 has a side surface F21 on the subpixel SP1 side and a side surface F22 on the subpixel SP2 side. The bottom layer 63 has an end portion E31 on the sub-pixel SP1 side, an end portion E32 on the sub-pixel SP2 side, and an upper surface U3.

In the example of FIG. 5, the end portion E11 of the upper portion 62 protrudes relative to the end portion E31 of the bottom layer 63 and the side surface F21 of the stem layer 64. Similarly, the end portion E12 of the upper portion 62 protrudes relative to the end portion E32 of the bottom layer 63 and the side surface F22 of the stem layer 64. Further, the end portion E31 of the bottom layer 63 protrudes relative to the side surface F21 of the stem layer 64. Similarly, the end portion E32 of the bottom layer 63 protrudes relative to the side surface F22 of the stem layer 64. In the example of FIG. 5, the width of the second top layer 66 is the same as that of the first top layer 65. The width of the second top layer 66 may be smaller than that of the first top layer 65. The stem layer 64 is formed to be thicker than the bottom layer 63, the first top layer 65, and the second top layer 66.

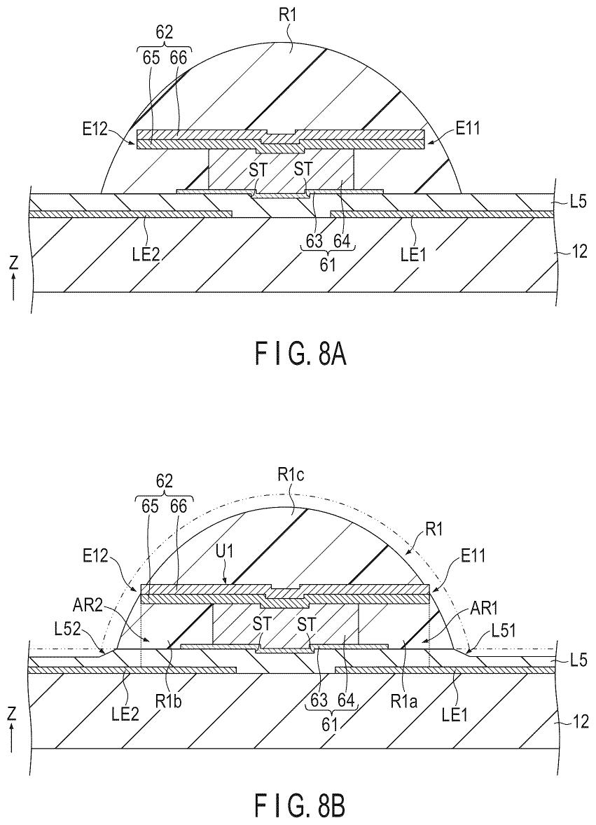

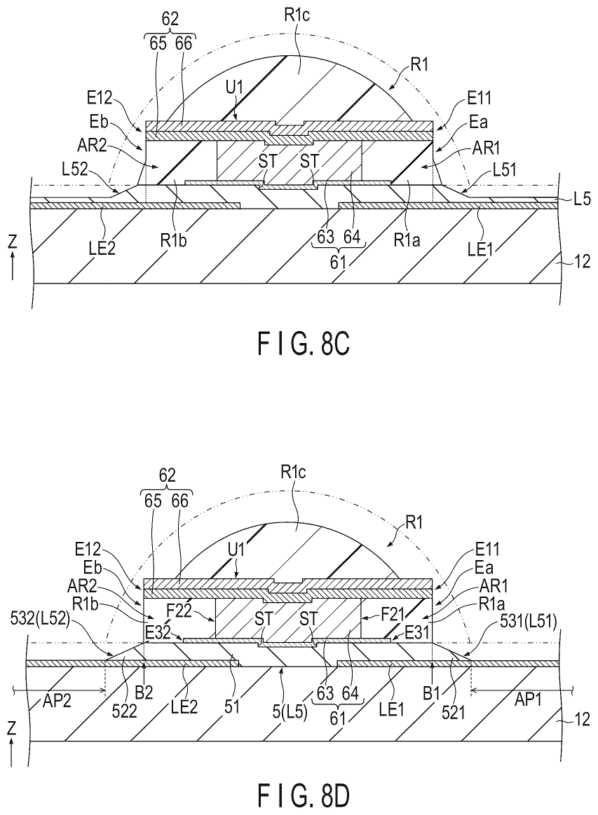

The rib 5 has a first portion 51 and second portions 521 and 522. The first portion 51 has the constant thicknesses in the rib 5. “Constant” includes not only a case involving no fluctuation in the thickness of the rib 5 according to the position in the X-Y plane but also a case involving slight fluctuation that is unintentionally formed. For example, the first portion 51 is an area that is not subjected to etching described later with reference to FIG. 8A to FIG. 8D. The second portion 521 is a portion of the rib 5 which decreases in thickness toward the pixel aperture AP1. The second portion 522 is a portion of the rib 5 which decreases in thickness toward the pixel aperture AP2. The first portion 51 is located between the second portions 521 and 522.

In the example of FIG. 5, a boundary B1 between the first portion 51 and the second portion 521 is aligned with the end portion E11 of the upper portion 62 in plan view. A boundary B2 between the first portion 51 and the second portion 522 is aligned with the end portion E12 of the upper portion 62 in plan view. As another example, the boundary B1 may be misaligned with the end portion E11. The boundary B2 may be misaligned with the end portion E12.

The first portion 51 has an upper surface U5. The second portion 521 has an inclined surface 531 sloping from the boundary B1 to the pixel aperture AP1. The second portion 522 has an inclined surface 532 sloping from the boundary B2 to the pixel aperture AP2. The lower electrode LE1 has an upper surface Uc1 and an end portion Ec1. The lower electrode LE2 has an upper surface Uc2 and an end portion Ec2. The end portions Ec1 and Ec2 overlap with the partition 6 in plan view. More specifically, the end portions Ec1 and Ec2 overlap with the stem layer 64 in plan view.

As shown in FIG. 5, step portions ST are formed on the upper surface U5 of the rib 5 due to the end portions Ec1 and Ec2 of the respective lower electrodes LE1 and LE2. In the present embodiment, these step portions ST are covered with the bottom layer 63 and the stem layer 64. As shown in FIG. 5, the upper surface of the stem layer 64, the first top layer 65, and the second top layer 66 may deform according to the step portions ST.

In the example of FIG. 5, an angle θ1 formed between the inclined surface 531 and the upper surface Uc1 of the lower electrode LE1 is the same as an angle θ2 formed between the inclined surface 532 and the upper surface Uc2 of the lower electrode LE2. The angle θ1 and the angle θ2 may be different from each other. For example, each of the angles θ1 and θ2 is less than or equal to 50 degrees.

As shown in FIG. 5, areas AR1 and AR2 are formed below the upper portion 62. The areas AR1 and AR2 are surrounded by the lower surface of the upper portion 62, the side surfaces of the lower portion 61, and the upper surface of the rib 5. More specifically, the area AR1 is surrounded by the lower surface L1 of the first top layer 65, the side surface F21 of the stem layer 64, the upper surface U3 of the bottom layer 63, the end portion E31 of the bottom layer 63, and the upper surface U5 of the first portion 51. Further, the area AR2 is surrounded by the lower surface L1 of the first top layer 65, the side surface F22 of the stem layer 64, the upper surface U3 of the bottom layer 63, the end portion E32 of the bottom layer 63, and the upper surface U5 of the first portion 51.

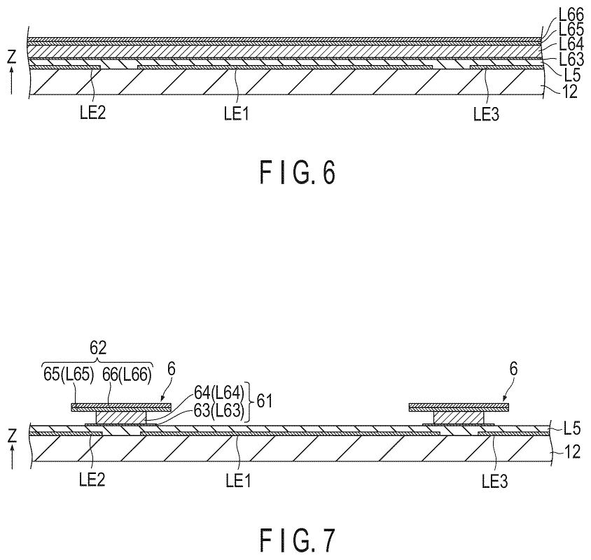

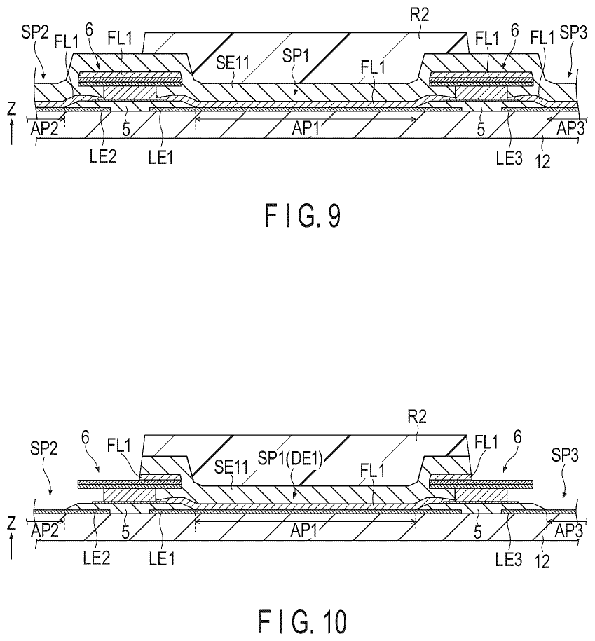

An example of a method of manufacturing the display device DSP according to the present embodiment will be described next. FIG. 6 to FIG. 15 are schematic cross-sectional views showing the manufacturing processes of the display device DSP of the present embodiment. In these figures, the illustrations of the substrate 10 and the circuit layer 11 are omitted. In addition, in FIG. 6, FIG. 7, and FIG. 9 to FIG. 15, illustration of the step portion ST due to the end portion of the lower electrode is omitted.

In the manufacturing of the display device DSP, first, the circuit layer 11, the organic insulating layer 12, and the lower electrodes LE1, LE2, and LE3 are formed on the substrate 10. Thereafter, as shown in FIG. 6, an insulating layer L5, which is to be processed into the rib 5, is formed on the organic insulating layer 12 and the lower electrodes LE1, LE2, and LE3. A first layer L63, which is to be processed into the bottom layer 63, is formed on an insulating layer L5. A second layer L64, which is to be processed into the stem layer 64, is formed on the first layer L63. A third layer L65, which is to be processed into the first top layer 65, is formed on the second layer L64. A fourth layer L66, which is to be processed into the second top layer 66, is formed on the third layer L65.

Next, the first layer L63, the second layer L64, the third layer L65, and the fourth layer L66 are subjected to patterning. This patterning includes a process of providing a resist having the planar shape of the partition 6 on the fourth layer L66, a process of etching the fourth layer L66 to form the second top layer 66, a process of etching the third layer L65 to form the first top layer 65, a process of etching the second layer L64 to form the stem layer 64, and a process of etching the first layer L63 to form the bottom layer 63. These processes form the partition 6 including the lower portion 61 and the upper portion 62 on the insulating layer L5 as shown in FIG. 7. As shown in FIG. 5, the lower portion 61 includes the bottom layer 63 and the stem layer 64. Further, as shown in FIG. 5, the upper portion 62 includes the first top layer 65 and the second top layer 66.

Next, the formation process of the rib 5 will be described with reference to FIG. 8A to FIG. 8D. Portions of the insulating layer L5 and partition 6 that are located between the lower electrodes LE1 and LE2 will be described with reference to FIG. 8A to FIG. 8D. Note that portions of the insulating layer L5 and partition 6 that are located between the lower electrodes LE1 and LE3 or between the lower electrodes LE2 and LE3 are formed in the same manner as the one shown in FIG. 8A to FIG. 8D.

First, as shown in FIG. 8A, a resist R1 covering the partition 6 is formed on the insulating layer L5. The resist R1 has a planar shape similar to that of the partition 6. For example, the resist R1 has a cross-sectional shape which decreases in thickness toward both ends. It is preferable that the size of the resist R1 is set such that the end portions E11 and E12 are not exposed from the resist R1. In the example of FIG. 8A, the end portions E11 and E12 of the upper portion 62 are covered with the resist R1.

Subsequently, as shown in FIG. 8B, anisotropic dry etching using the resist R1 as a mask is performed for the insulating layer L5. The two-dot chain line shown in each of FIG. 8B to 8D shows the outer shape of the insulating layer L5 and the resist R1 before the etching. Further, in the etching, a portion that is exposed from the resist R1 of the insulating layer L5 is corroded. In the etching, the resist R1 is corroded as well. Therefore, the resist R1 gradually decreases in width in the etching. Next, as shown in FIG. 8B, inclined surfaces L51 and L52 are formed on the insulating layer L5.

By the resist R1 gradually decreasing in width in the etching, a part of each of the end portions E11 and E12 and a part of the upper surface U1 are exposed. Thus, the partition 6 partitions the resist R1 into a resist R1a located on the area AR1 side of the resist located below the upper portion 62, a resist R1b located on the area AR2 side of the resist located below the upper portion 62, and a resist R1c located above the upper portion 62. The second top layer 66 is formed of a conductive oxide and thus is less susceptible to the etching. Therefore, a portion that is exposed from the resist R1c of the upper surface U1 and the end portions E11 and E12 are substantially not corroded.

The resist R1 further decreases in width as the etching processes, and the end portions E11 and E12 of the upper portion 62 become completely exposed as shown in FIG. 8C. The resist R1a in the area AR1 and the resist R1b in the area AR2 are located directly below the upper portion 62 in the third direction Z. As a result, the upper portion 62 can prevent the corrosion of the resist R1a in the area AR1 and the resist R1b in the area AR2. In contrast, the resist R1a located outside the area AR1 and the resist R1b located outside the area AR2 do not overlap with the upper portion 62 in plan view and thus are corroded in this etching. Therefore, an end portion Ea aligned with the end portion E11 of the upper portion 62 is formed on the resist R1a in the third direction Z. Similarly, an end portion Eb aligned with the end portion E12 of the upper portion 62 is formed on the resist R1b in the third direction Z. A protective film for preventing corrosions due to the etching may be formed on the end portions Ea and Eb in the etching.

As the etching further progresses, the resist R1 further decreases in width as shown in FIG. 8D. As a result, portions that are exposed from the resists R1a and R1b of the insulating layer L5 are removed by the etching, and the rib 5 and the pixel apertures AP1 and AP2 surrounded by the rib 5 are formed. In addition, this etching forms, on the rib 5, the first portion 51 having the constant thickness, the second portion 521, which decreases in thicknesses toward the pixel aperture AP1, and the second portion 522, which decreases in thickness toward the pixel aperture AP2. The inclined surface 531, which slops from the boundary B1 between the first portion 51 and the second portion 521 to the pixel aperture AP1, is formed on the second portion 521. Similarly, the inclined surface 532, which slops from the boundary B2 between the first portion 51 and the second portion 522 to the pixel aperture AP2, is formed on the second portion 532. This etching ends when the rib 5 and the pixel apertures AP1 and AP2 are formed. After this etching, the resist R1 is removed.

At the end of the etching, the resist R1a remains in the area AR1 and the resist R1b remains in the area AR2 as shown in FIG. 8D. Further, the resist R1c remains on the upper surface U1 of the upper portion 62. Further, the resist R1a covers the lower surface L1 of the first top layer 65 in the area AR1, the side surface F21 of the stem layer 64, the end portion E31 of the bottom layer 63, and the upper surface U5 of the first portion 51 in the area AR1. Similarly, the resist R1b covers the lower surface L1 of the first top layer 65 in the area AR2, the side surface F22 of the stem layer 64, the end portion E32 of the bottom layer 63, and the upper surface U5 of the first portion 51 in the area AR2. In the example of FIG. 8D, the end portion E11 of the upper portion 62, an end portion Ea of the resist R1a, and the boundary B1 are aligned with one another in plan view. Similarly, the end portion E12 of the upper portion 62, the end portion Eb of the resist R1b, and the boundary B2 are aligned with one another in plan view.

After the formation of the rib 5, a process for forming the display elements DE1, DE2, and DE3 is performed. The present embodiment assumes a case where the display element DE1 is formed first, the display element DE2 is formed next, and the display element DE3 is formed last. The formation order of the display elements DE1, DE2, and DE3 is not limited to this example.

In the formation of the display element DE1, the stacked film FL1 and the sealing layer SE11 are formed first as shown in FIG. 9. As shown in FIG. 3, the stacked film FL1 includes, the organic layer OR1, which is in contact with the lower electrode LE1 through the pixel aperture AP1, the upper electrode UE1, which covers the organic layer OR1, and the cap layer CP1, which covers the upper electrode UE1.

The organic layer OR1, the upper electrode UE1, and the cap layer CP1 are formed by vapor deposition. The sealing layer SE11 is formed by chemical vapor deposition (CVD). The stacked film FL1 is divided into a plurality of portions by the partition 6 having an overhang shape. The sealing layer SE11 continuously covers these portions, into which the stacked film FL1 has been divided, and the partition 6.

After the formation of the stacked film FL1 and the sealing layer SE11, a resist R2 is provided on the sealing layer SE11 as shown in FIG. 9. The resist R2 covers the subpixel SP1 and a part of the partition 6 around the subpixel SP1.

Subsequently, as shown in FIG. 10, portions that are exposed from the resist R2 of the stacked film FL1 and sealing layer SE11 are removed by etching using the resist R2 as a mask. This process forms the display element DE1 in the subpixel SP1. For example, this etching includes wet etching and dry etching processes, which are performed in order for the sealing layer SE11, the cap layer CP1, the upper electrode UE1, and the organic layer OR1. After these etching processes, the resist R2 is removed.

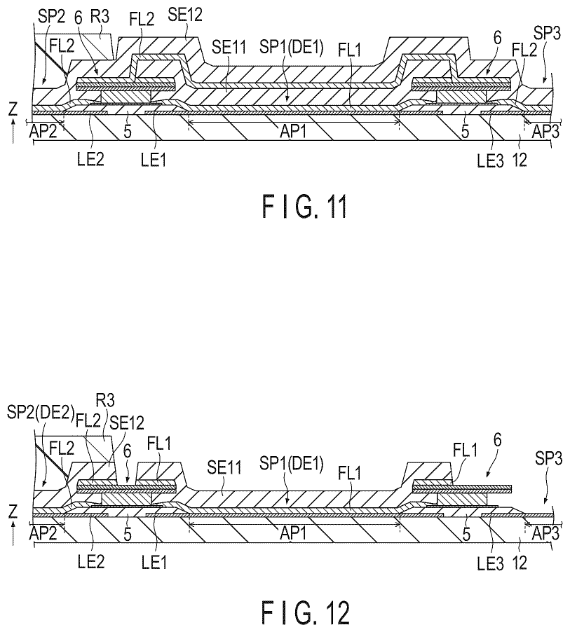

The display element DE2 is formed by a procedure similar to that of the display element DE1. That is, as shown in FIG. 11, the stacked film FL2 and the sealing layer SE12 are formed in the formation of the display element DE2. The stacked film FL2 includes the organic layer OR2, which is in contact with the lower electrode LE2 through the pixel aperture AP2, the upper electrode UE2, which covers the organic layer OR2, and the cap layer CP2, which covers the upper electrode UE2, as shown in FIG. 3.

The organic layer OR2, the upper electrode UE2, and the cap layer CP2 are formed by vapor deposition. The sealing layer SE12 is formed by CVD. The stacked film FL2 is divided into a plurality of portions by the partition 6 having an overhang shape. The sealing layer SE12 continuously covers these portions, into which the stacked film FL2 has been divided, and the partition 6.

After the formation of the stacked film FL2 and the sealing layer SE12, a resist R3 is provided on the sealing layer SE12, as shown in FIG. 11. The resist R3 covers the subpixel SP2 and a part of the partition 6 around the subpixel SP2.

Subsequently, as shown in FIG. 12, portions that are exposed from the resist R3 of the stacked film FL2 and sealing layer SE12 are removed by etching using the resist R3 as a mask. This process forms the display element DE2 in the subpixel SP2. For example, this etching includes wet etching and dry etching processes, which are performed in order for the sealing layer SE12, the cap layer CP2, the upper electrode UE2, and the organic layer OR2. After these etching processes, the resist R3 is removed.

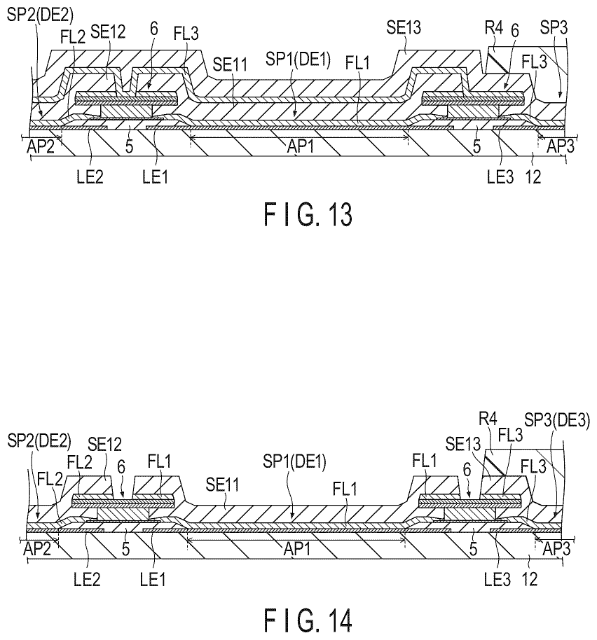

The display element DE3 is formed by a procedure similar to the procedures of the display elements DE1 and DE2. That is, as shown in FIG. 13, the stacked film FL3 and the sealing layer SE13 are formed in the formation of the display element DE3. The stacked film FL3 includes, the organic layer OR3, which is in contact with the lower electrode LE3 through the pixel aperture AP3, the upper electrode UE3, which covers the organic layer OR3, and the cap layer CP3, which covers the upper electrode UE3, as shown in FIG. 3.

The organic layer OR3, the upper electrode UE3, and the cap layer CP3 are formed by vapor deposition. The sealing layer SE13 is formed by CVD. The stacked film FL3 is divided into a plurality of portions by the partition 6 having an overhang shape. The sealing layer SE13 continuously covers these portions, into which the stacked film FL3 has been divided, and the partition 6.

After the formation of the stacked film FL3 and the sealing layer SE13, a resist R4 is provided on the sealing layer SE13, as shown in FIG. 13. The resist R4 covers the subpixel SP3 and a part of the partition 6 around the subpixel SP3.

Subsequently, as shown in FIG. 14, portions that are exposed from the resist R4 of the stacked film FL3 and sealing layer SE13 are removed by etching using the resist R4 as a mask. By this process, the display element DE3 is formed in the subpixel SP3. For example, this etching includes wet etching and dry etching processes, which are performed in order for the sealing layer SE13, the cap layer CP3, the upper electrode UE3, and the organic layer OR3. After these etching processes, the resist R3 is removed.

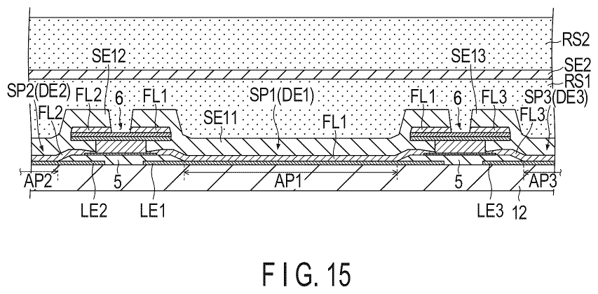

After the formations of the display elements DE1, DE2, and DE3, the resin layer RS1, the sealing layer SE2, and the resin layer RS2 are formed in order as shown in FIG. 15. The display device DSP is completed through these processes.

In the present embodiment, the resist R1 decreases in width by anisotropic dry etching performed in the process of forming the rib 5 and the pixel apertures AP1 and AP2, and this decrease makes the end portions E11 and E12 of the upper portion 62 exposed as shown in FIG. 8A to FIG. 8D. That is, the partition 6 partitions the resist R1 into the resists R1a and R1b located below the upper portion 62 and the resist R1c located above the upper portion 62. Portions that overlap with the upper portion 62 of the resists R1a and R1b are substantially not corroded since the etching is blocked by the upper portion 62. This etching forms the pixel apertures AP1 and AP2 on the rib 5 such that the end portion E11 of the upper portion 62 and the boundary B1 between the first portion 51 and the second portion 521 are aligned with each other in plan view and the end portion E12 of the upper portion 62 and the boundary B2 between the first portion 51 and the second portion 522 are aligned with each other in plan view. That is, the width of the first portion 51 of the rib 5 depends on the width of the upper portion 62. The above point applies to the first portion 51 located between the pixel apertures AP1 and AP3 or between the pixel apertures AP2 and AP3.

In contrast, when the coating amount of the resist R1 is large, the etching ends before the resist R1 being partitioned by the partition 6. That is, the width of the first portion 51 of the rib 5 depends on the width of the resist R1 at the end of the etching. Thus, the sizes and positions of pixel apertures formed in pixels may be different from each other due to the variation in the coating amount of the resist.

In contrast, as described above, the width of the first portion 51 of the rib 5 in the present embodiment depends on the width of the upper portion 62. Thus, the sizes and positions of pixel apertures formed in pixels can be substantially equivalent to one another. Further, compared to a case where the coating amount of the resist is large, the greater pixel aperture can be formed.

According to the manufacturing method of the display device DSP of the present embodiment, the yields at the time of manufacturing of the display device DSP can be improved. Various other desirable effects can be obtained from the present embodiment.

All of the manufacturing methods of a display device that can be implemented by a person of ordinary skill in the art through arbitrary design changes to the manufacturing method described above as the embodiment of the present invention come within the scope of the present invention as long as they are in keeping with the spirit of the present invention.

Various types of the modified examples are easily conceivable within the category of the ideas of the present invention by a person of ordinary skill in the art, and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device manufacturing method, comprising:
forming a lower electrode;
forming an insulating layer on the lower electrode;
forming a partition including a lower portion provided above the insulating layer and an upper portion having an end portion protruding relative to a side surface of the lower portion;
providing a resist covering the partition on the insulating layer;
forming a rib and a pixel aperture surrounded by the rib by removing a portion exposed from the resist of the insulating layer by etching;
forming an organic layer covering the lower electrode through the pixel aperture and emitting light in response to application of a voltage; and
forming an upper electrode covering the organic layer, wherein
the end portion of the upper portion is exposed from the resist in the etching.

2. The display device manufacturing method of claim 1, wherein
the resist gradually decreases in width by the etching.

3. The display device manufacturing method of claim 1, wherein
at the end of the etching, the resist remains in an area surrounded by a lower surface of the upper portion, the side surface of the lower portion, and an upper surface of the rib.

4. The display device manufacturing method of claim 3, wherein
at the end of the etching, the end portion of the upper portion and an end portion of the resist remaining in the area are aligned with each other in plan view.

5. The display device manufacturing method of claim 1, wherein
at the end of the etching, the resist remains on the upper surface of the upper portion.

6. The display device manufacturing method of claim 1, wherein
the rib including a first portion having a constant thickness and a second portion decreasing in thicknesses toward the pixel aperture is formed by the etching.

7. The display device manufacturing method of claim 6, wherein
at the end of the etching, the end portion of the upper portion and a boundary between the first portion and the second portion are aligned with each other in plan view.

8. The display device manufacturing method of claim 7, wherein
the second portion has an inclined surface sloping from the boundary to the pixel aperture, and
an angle formed between the inclined surface and an upper surface of the lower electrode is less than or equal to 50 degrees.

9. The display device manufacturing method of claim 1, wherein
an end portion of the lower electrode overlaps with the partition in plan view.

10. The display device manufacturing method of claim 1, wherein
the upper portion includes a first top layer provided on the lower portion and a second top layer provided on the first top layer, and
the second top layer is formed of a conductive oxide.

11. The display device manufacturing method of claim 10, wherein
at the end of the etching, a lower surface of the first top layer is covered with the resist.

12. The display device manufacturing method of claim 1, wherein
the lower portion includes a stem layer and a bottom layer provided between the stem layer and the rib, and
an end portion of the bottom layer is located between the end portion of the upper portion and the side surface of the stem layer in plan view.

13. The display device manufacturing method of claim 12, wherein
an end portion of the lower electrode overlaps with the stem layer in plan view.

14. The display device manufacturing method of claim 12, wherein
at the end of the etching, the end portion of the bottom layer is covered with the resist.

15. The display device manufacturing method of claim 12, wherein
at the end of the etching, the side surface of the stem layer is covered with the resist.

16. The display device manufacturing method of claim 1, wherein
the etching is dry etching.

17. The display device manufacturing method of claim 1, wherein
the etching is anisotropic etching.
